(19) United States
(12) Patent Application Publication
(10) Pub. No.: US 2025/0272058 A1
(43) Pub. Date: Aug. 28, 2025

(54) Three-Dimensional Phase-Change Memory Array Operable to Perform Multiplication Accumulation Operations

(71) Applicant: Micron Technology, Inc., Boise, ID (US)

(72) Inventors: Kamal Karda, Boise, ID (US); Hernan Castro, Shingle Springs, CA (US)

(21) Appl. No.: 18/787,950

(22) Filed: Jul. 29, 2024

Related U.S. Application Data
(60) Provisional application No. 63/557,006, filed on Feb. 23, 2024.

(51) Int. Cl. G06F 7/50; G06F 7/523; G11C 25/00

(52) U.S. Cl. CPC G06F 7/50; G06F 7/523; G11C 25/00

(57) ABSTRACT

A memory device having: a first local digit line configured to extend in a first direction; a second local digit line configured in parallel with the first local digit line; a plurality of unit cells stacked in the first direction and sandwiched between the first local digit line and the second local digit line, each respective unit cell among the plurality of unit cells configured to connect the first local digit line to the second local digit line in a second direction that is perpendicular to the first direction, the respective unit cell having a transistor and a memory cell; and a plurality of wordlines configured to extend in a third direction that is perpendicular to the first direction and the second direction, where transistors in the plurality of unit cells are connected to the wordlines.

### RELATED APPLICATIONS

The present application claims priority to Prov. U.S. Pat. App. Ser. No. 63/557,006 filed Feb. 23, 2024, the entire disclosures of which application are hereby incorporated herein by reference.

### TECHNICAL FIELD

At least some embodiments disclosed herein relate to three-dimensional memory array structures in general and more particularly, but not limited to, memory array structures for in-memory computations of multiplication and accumulation.

### BACKGROUND

Many techniques have been developed to accelerate the computations of multiplication and accumulation. For example, multiple sets of logic circuits can be configured in arrays to perform multiplications and accumulations in parallel to accelerate multiplication and accumulation operations. For example, a memory sub-system can use a memristor crossbar or array to accelerate multiplication and accumulation operations in the electrical domain.

A memory sub-system can include one or more memory devices that store data. The memory devices can be, for example, non-volatile memory devices and volatile memory devices. In general, a host system can utilize a memory sub-system to store data at the memory devices and to retrieve data from the memory devices.

### BRIEF DESCRIPTION OF THE DRAWINGS

The embodiments are illustrated by way of example and not limitation in the figures of the accompanying drawings in which like references indicate similar elements.

FIG. 1 illustrates a three-dimensional structure of a stack of memory cells according to one embodiment.

FIG. 2 shows a unit cell in a memory array according to one embodiment.

FIG. 3 shows a memory cell configured in a unit cell according to one embodiment.

FIG. 4 shows a unit cell according to one embodiment.

FIG. 5 illustrates the structure of a stack of memory cells in a vertical plane according to one embodiment.

FIG. 6 illustrates the structure of a memory cell array in a horizontal plane passing through a set of parallel unit cells configured according to one embodiment.

FIG. 7 illustrates the structure of a memory cell array in a horizontal plane passing through a wordline above a set of parallel unit cells configured according to one embodiment.

FIG. 8 shows a circuit representation of a stack of memory cells configured in a three dimensional array according to one embodiment.

FIG. 9 illustrates a configuration of multiple adjacent memory cells connected to store multiple bits of a weight according to one embodiment.

FIG. 10 shows the computation of a column of weight bits multiplied by a column of input bits to provide an accumulation result according to one embodiment.

FIG. 11 shows the computation of a column of multi-bit weights multiplied by a column of input bits to provide an accumulation result according to one embodiment.

FIG. 12 shows the computation of a column of multi-bit weights multiplied by a column of multi-bit inputs to provide an accumulation result according to one embodiment.

FIG. 13 shows an example computing system having a memory sub-system configured to perform multiplication and accumulation operations according to one embodiment.

FIG. 14 shows a method to perform operations of multiplication and accumulation according to one embodiment.

### DETAILED DESCRIPTION

At least one embodiment disclosed herein provides a high density memory cell array. Memory cells can be configured in a three-dimensional array and connected in a way to support in-memory computations of multiplication and accumulation. For example, the memory cells in the array can be implemented via phase-change material. Each of the memory cells can have an associated transistor. A phase-change memory cell and its associated transistor can be implemented as a cell unit; and cell units can be configured in a three dimensional array to provide the three-dimensional array of memory cells. Such a memory cell array can be highly energy efficient, especially in frequent data modifications (e.g., as in the application of training the weights of an artificial neural network).

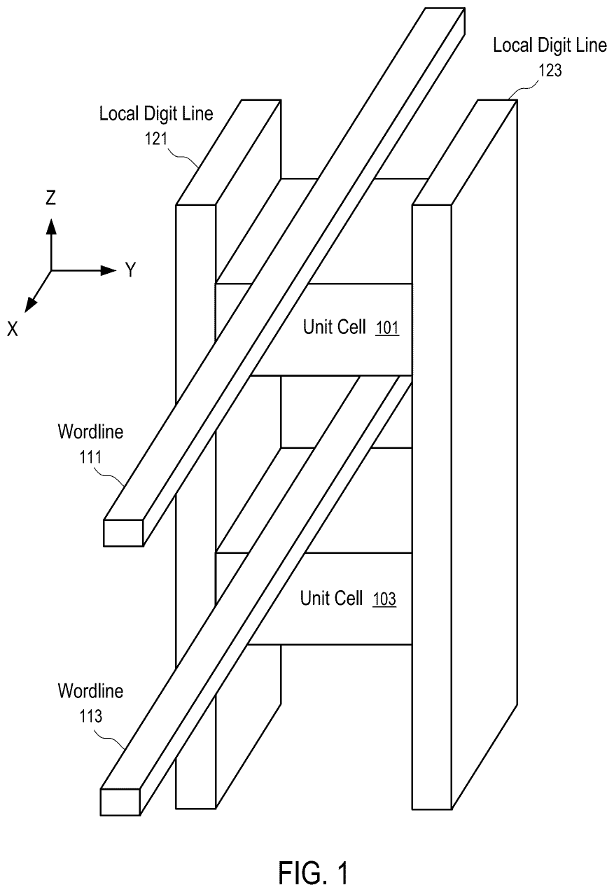

FIG. 1 illustrates a three-dimensional structure of a stack of memory cells according to one embodiment.

In FIG. 1, layers of unit cells (e.g., 101, 103) are stacked in a vertical direction (e.g., along Z-axis). Each unit cell (e.g., 101, 103) contains a transistor connected to a memory cell. The gate of the transistor is connected to a wordline (e.g., 111 or 113) that is configured to extend in a first horizontal direction (e.g., along X-axis) and control memory cells in stacks arranged in the first horizontal direction (e.g., along X-axis). The structure of the stacks of memory cells can be repeated in a second horizontal direction (e.g., along Y-axis) to form a three-dimensional array.

A pair of local digit lines (e.g., 121 and 123) are configured to extend in the vertical direction (e.g., along Z-axis) to connect the memory cells in the stacks. Each unit cell (e.g., 101) connects a point on one local digit line (e.g., 121) to another point on the other local digit line (e.g., 123) in the second horizontal direction (e.g., along Y-axis).

The currents going through the unit cells (e.g., 101, 103) in the stacks are summed in the local digit lines (e.g., 121 and 123) to implement accumulation operations.

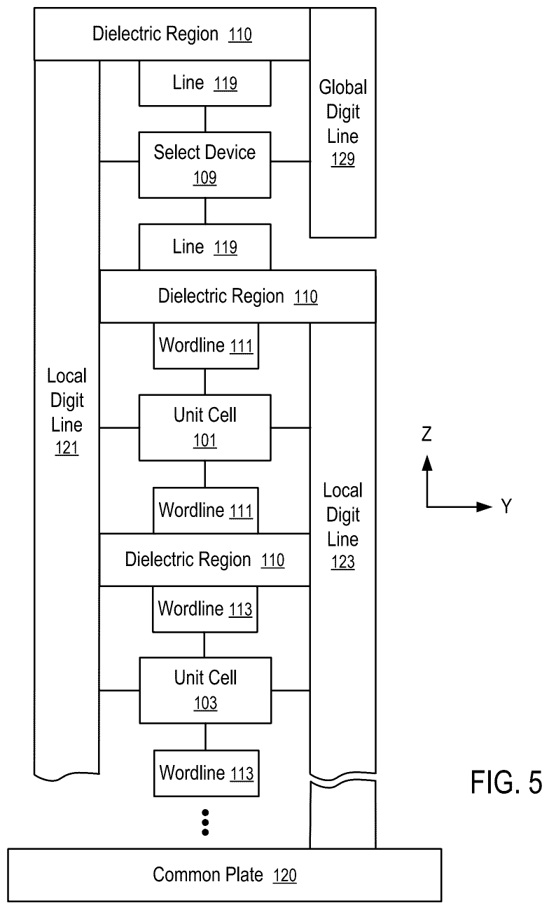

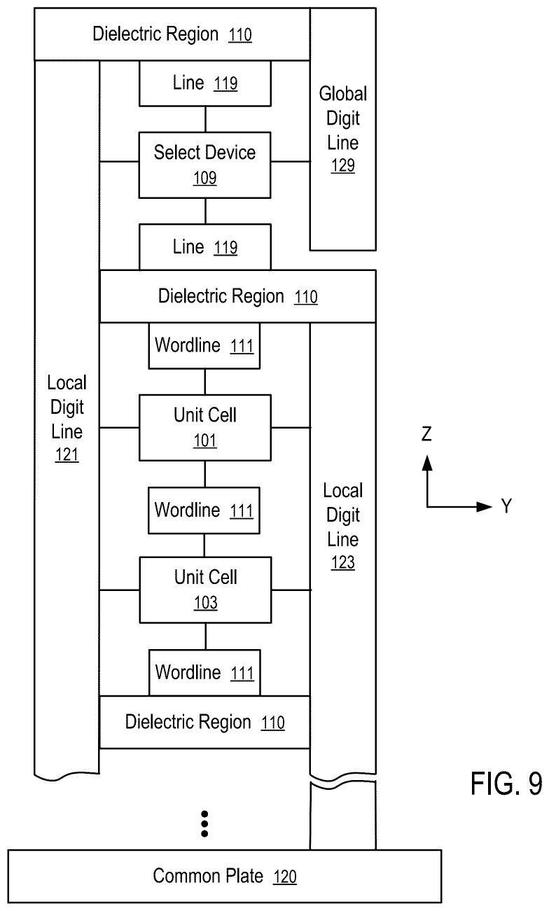

One local digit line (e.g., 123) in the pair can be configured to be connected to a common conductive plane positioned at the bottom of multiple stacks. The other local digit line (e.g., 123) can be connected to a select device to a global digit line (e.g., as illustrated in FIG. 5 and FIG. 9).

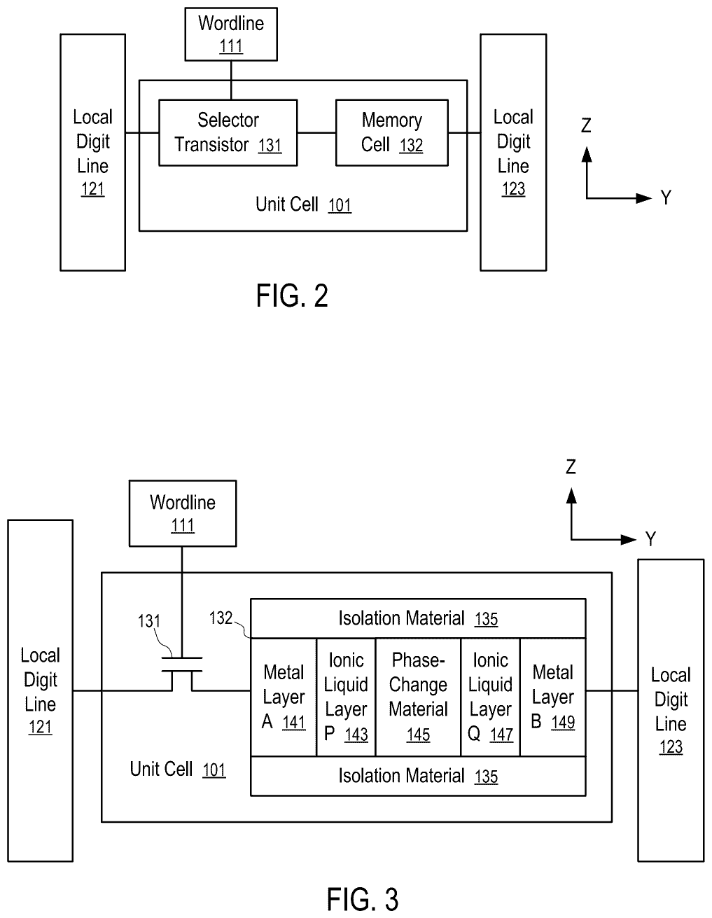

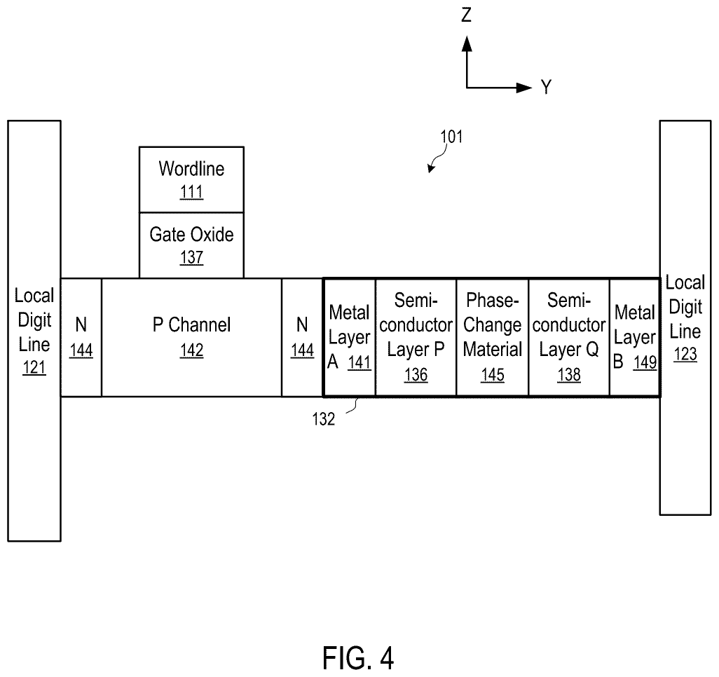

Each unit cell (e.g., 101 or 103) can be implemented in a way as illustrated in FIG. 2, FIG. 3, and/or FIG. 4.

FIG. 2 shows a unit cell in a memory array according to one embodiment.

In FIG. 2, a unit cell 101 (e.g., as in the stack shown in FIG. 1) can have a selector transistor 131 and a memory cell 132. A current going through the memory cell 132, in response to voltages applied via the local digit lines 121 and 123 and controlled by the wordline 111, is representative of a result of multiplication in an applied voltage and data store in the memory cell 132.

In at least some embodiments, the memory cell 132 has a structure as in FIG. 3.

FIG. 3 shows a memory cell configured in a unit cell according to one embodiment.

In FIG. 3, the unit cell 101 has a plurality of layers of materials stacked in the second horizontal direction (e.g., along Y-axis) going from one local digit line 121 to another local digit line 123.

The plurality of layers of materials include a metal layer 141 connected to the selector transistor 131, and another metal layer 149 connected to a local digit line 123.

A phase-change material 145 is sandwiched between two ionic liquid layers (143 and 147), which are sandwiched between the metal layers 141 and 149.

Isolation material 135 is configured around the memory cell 132 to separate the memory cell 132 from a portion of the unit cell 101 configured to implement the select transistor 131.

In at least some embodiments, the selector transistor 131 in FIG. 2 and/or FIG. 3 is implemented in a way as in FIG. 4.

FIG. 4 shows a unit cell according to one embodiment.

In FIG. 4, a select transistor 131 is implemented via an NMOS having a P channel 142 sandwich between two N regions 144 to provide an N+P−N+ channel. Alternatively, an N-channel sandwich between two P regions can be used to implement the select transistor 131. For example, a P+N-P+ channel can be used. In some implementations, the channel 142 can be substantially undoped.

In FIG. 4, the N+P−N+ channel between the N regions 144 extends from the local digit line 121 to the metal layer 141 of the memory cell 132 to connect the local digit line 121 to the memory cell 132. The wordline 111 controls the gate over the gate oxide 137 to selectively open or close the N+P−N+ channel and thus select or deselect the memory cell 132 based on the signal/voltage applied on the wordline 111.

In FIG. 4, a wordline 111 has a portion configured on top of the unit cell 101 and connected to control a gate of the NMOS.

When the memory cell 132 is configured in a way as in FIG. 3 and/or FIG. 4, the write voltage for the memory cell 132 can be +2V or −2V with 3V on the select transistor. Such operating voltages for writing data to the memory cell 132 can be significantly lower than what is required to write to a NAND (or NOR) memory cell, leading to significant improvement in power efficiency in applications with frequent write operations (e.g., during training of an artificial neural network where the memory cells are used to store the weights being trained).

In some implementations, each layer in the metal layers 141 and 149, the semiconductor layers 136 and 138, and the phase-change material 145 can be formed via applying one or more layers of material during the construction of the memory cell 132. Thus, the indication of a layer of material in the unit cell 101 is not necessarily an indication of a single processing operation of applying a single layer during manufacturing of the memory device.

FIG. 5 illustrates the structure of a stack of memory cells in a vertical plane according to one embodiment.

In FIG. 5, a stack of unit cells (e.g., 101, 103) are arranged in the vertical direction (e.g., along Z-axis). For example, the three-dimensional structure of the unit cells (e.g., 101, 103) can be configured in a way similar to what is illustrated in FIG. 1.

Adjacent layers of unit cells (e.g., 101 and 103) stacked in the vertical direction (e.g., along Z-axis) can be separated by a layer of dielectric region 110 configured on a substrate of a semiconductive device.

Each unit cell (e.g., 101, or 103) in the stack can be configured to have a selector transistor (e.g., 131) and a memory cell (e.g., 132) in a way as in FIG. 2, FIG. 3, and/or FIG. 4.

In the top layer of the stack, a select device 109 is configured in a way similar to a selector transistor (e.g., 131) of a unit cell (e.g., 101) but without a memory cell (e.g., 132). The select device 109 is connected to a control line 119. The signal on the control line 119 can be used to control whether to connect the local digit line 121 to a global digit line 129.

For example, the signal on the control line 119 can be generated to connect the local digit line 121 to the global digit line 129 when any of the wordlines (e.g., 111, 113) is active to turn on the switch transistor(s) in the stack of the unit cells (e.g., 101, 103).

For example, the signal on the control line 119 can be generated to disconnect the local digit line 121 from the global digit line 129 when no current passing through any of the unit cells (e.g., 101, 103) is to be connected into the global digit line 129.

The current from the global digit line 129 can be measured via a current sensor to determine the sum of currents going through the stack of unit cells (e.g., 101, 103).

Optionally, currents from global digit lines (e.g., 129) of some stacks of unit cells can be connected into a common line for summation computation in an analog form.

The local digit line 123 can be connected to a conductive common plate shared by stacks of unit cells. For example, the common plate can be configured at a layer positioned at the bottom of the stacks.

The structure of the stack of unit cells (e.g., 101, 103) with a top select device 109, a global digit line 129, and two local digit lines 121 and 123 can be repeated or replicated in both horizontal directions (e.g., X-axis and Y-axis) to form a three-dimensional array.

For convenience, a horizontal array of unit cells aligned in an XY-plane can be referred to, in the disclosure, as a plane of the three-dimensional array; a vertical array of unit cells aligned in an XZ-plane can be referred to, in the disclosure, as a slice of the three-dimensional array; and a vertical array of unit cells aligned in a YZ-plane can be referred to, in the disclosure, as a sliver of the three-dimensional array.

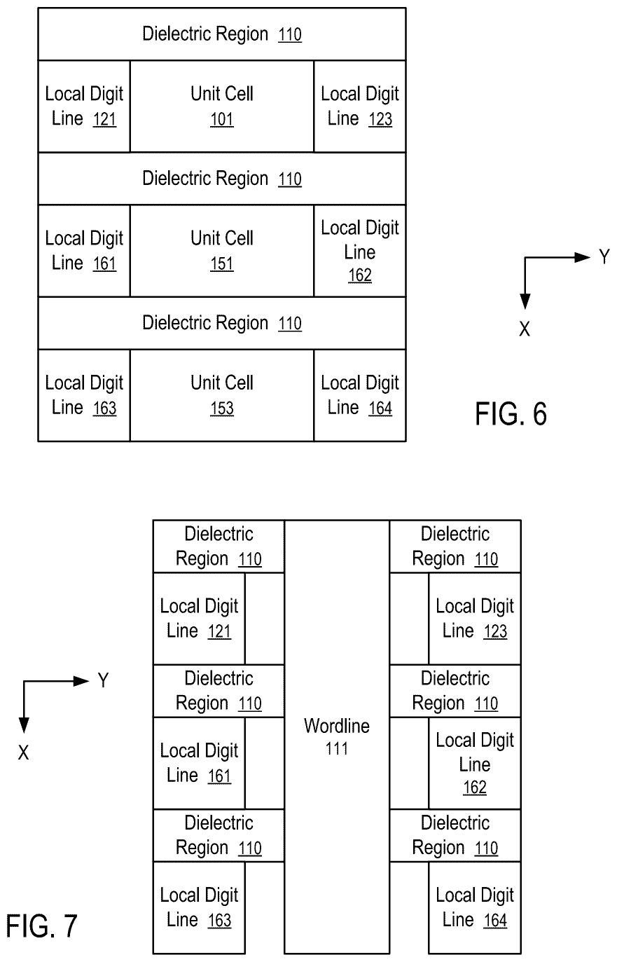

FIG. 6 illustrates the structure of a memory cell array in a horizontal plane passing through a set of parallel unit cells configured according to one embodiment.

For example, the vertical structure illustrated in FIG. 5 can be replicated in a horizontal direction (e.g., X-axis) to have a horizontal structure across a plane of unit cells (e.g., 101, 151, 153) as in FIG. 6.

In FIG. 6, dielectric regions 110 are configured to separate the slivers of unit cells.

In FIG. 6, a stack of unit cells (e.g., 151) is connected between a pair of local digit lines 161 and 162, in a way similar to a stack of unit cells (e.g., 101, 103) being connected between a pair of local digit lines 121 and 123 in FIG. 5.

Similarly, a stack of unit cells (e.g., 153) is connected between a pair of local digit lines 163 and 163, in a way similar to the stack of unit cells (e.g., 101, 103) being connected between a pair of local digit lines 121 and 123 in FIG. 5.

The local digit lines 162 and 164 can be connected to a common plate 120, in a way similar to the local digit line 123 being connected to the common plate 120 in FIG. 5.

The local digit lines 161 and 163 can be connected to their respective global digit lines (not shown) via their respective select devices (not shown) in a top layer, in a way similar to the local digit line 121 being connected to its global digit line 129 via its respective select device 109 in FIG. 5.

The selector transistors (e.g., 131) in a column of unit cells (e.g., 101, 151, 153) extending in the X-axis are controlled by a shared wordline (e.g., 111).

The structure as illustrated in FIG. 6 can be repeated or replicated in the direction of Y-axis.

FIG. 7 illustrates the structure of a memory cell array in a horizontal plane passing through a wordline above a set of parallel unit cells configured according to one embodiment.

For example, the structure of FIG. 7 can be implemented for a plane passing through the wordline 111 above (or below) the unit cell 101 in FIG. 5.

In FIG. 7, the wordline 111 extends through the dielectric regions 110 to control the selector transistors (e.g., 131) of the column of unit cells (e.g., 101, 151, 153 in FIG. 6) that are below (or above) the plane of the wordline 111 illustrated in FIG. 7.

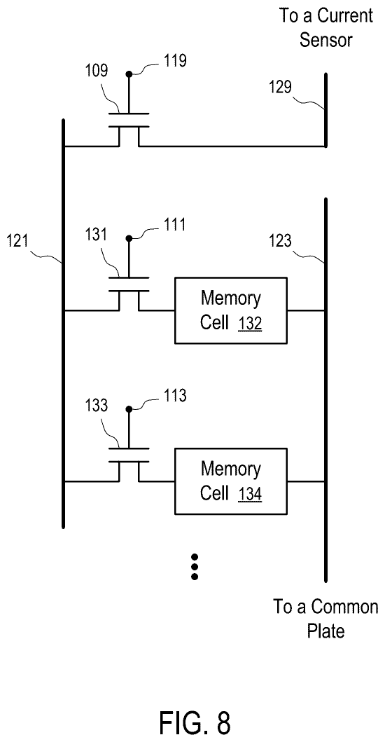

FIG. 8 shows a circuit representation of a stack of memory cells configured in a three dimensional array according to one embodiment.

In FIG. 8, a stack of memory cells 132, 134 (e.g., implemented in a stack of unit cells 101, 103 in FIG. 1 and/or FIG. 5) are connected between local digit lines 121 and 123 via their respective select transistors 131, 133.

Currents going through the memory cells 132, 134 are controlled by the voltages applied by wordlines 111, 113 to the gates of the respective select transistors 131, 133, and the voltage applied between the global digit line 129 and the common plate.

The select device 109 can be controlled via the line 119 to selectively turn on or off the stack of memory cells 132, 134 and their contributions of current to the global digit line 129.

The currents from the stack of memory cells and summed into the global digit line 129 can be connected to a current sensor to determine a result of multiplication and accumulation implemented in terms of data stored in the memory cells 132, 134 and data representative of voltages applied to the memory cells 132, 134.

In some applications, a memory cell 132 is programmed to have a state representing a bit of zero or one. When the gate of a select transistor (e.g., 131) of a memory cell (e.g., 132) is applied a voltage representative of one, the memory cell (e.g., 132) is to allow a predetermined amount of current to pass through when the data stored in the memory cell is one, and an insignificant amount of current to pass through when the memory cell (e.g., 132) is programmed to store a bit value of zero. When the gate of the select transistor (e.g., 131) of the memory cell (e.g., 132) is applied a voltage representative of zero, the transistor (e.g., 131) disconnects the memory cell (e.g., 132). Thus, the amount of current passing through the memory cell 132 and going into the global digit line 129 through the local digit line 121 as a multiple of the predetermined amount corresponds to the result of multiplication of the data representative of the voltage applied to the wordline 111 and the data stored in the memory cell 132.

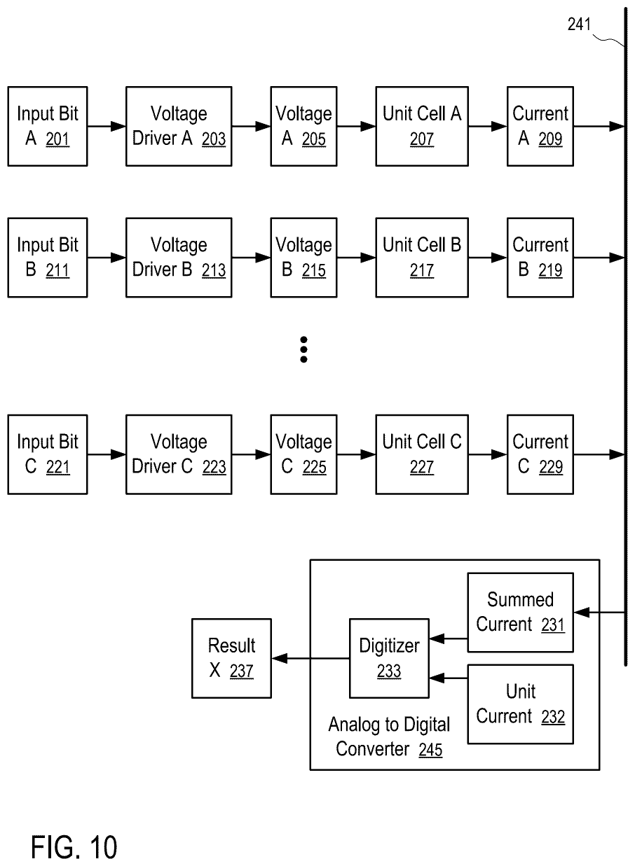

Thus, the stack of memory cells 132, 134 can be used to store weights and used as a multiplication and accumulation unit, in performing multiplication and accumulation operations in memory (e.g., to compute inputs, represented by voltages applied to wordlines 111, 113, as weighted by the weights stored in the memory cells 132, 134), as further discussed in connection with FIG. 10 to FIG. 12.

In some applications, each memory cell (e.g., 132) is programmed to store multiple bits of data. When the gate of the selection transistor (e.g., 131) is applied a voltage representative of one, the memory cell (e.g., 132) is configured to output an amount of current that is proportional to the value stored in the memory cell.

In some applications, multiple memory cells (e.g., 132, 134) in the stack are combined to store a value of weight. When the gates of selector transistors of the memory cells (e.g., 132, 134) are applied a voltage representative of one, the combined amount of currents passing through the memory cells (e.g., 132, 134) is a multiple of a predetermined amount of current.

When the multiple memory cells (e.g., 132, 134) in the stack are combined to store a value of weight, the wordlines connecting to the memory cells (e.g., 132, 134) can be shorted (e.g., via a circuit outside of the stack), or combined in the implementation of the stack, as illustrated in FIG. 9.

FIG. 9 illustrates a configuration of multiple adjacent memory cells connected to store multiple bits of a weight according to one embodiment.

FIG. 9 illustrates a view of a stack in unit cells (e.g., 101, 103) similar to the stack shown in FIG. 5.

In FIG. 9, the unit cells 101 and 103 are designed to be used together to store a value. Thus, a dielectric region 110 used in FIG. 5 to separate the unit cells 101 and 103 can be omitted in FIG. 9. A wordline 111 configured on a layer between the unit cell 101 and 103 can be shared by the unit cells 101 and 103. Thus, the density of unit cells in the array can be improved; and the height of the stack having a predetermined number of unit cells can be reduced.

FIG. 9 illustrates an example of grouping two adjacent memory cells in a stack to store a value for a wordline 111. In general, more than two adjacent memory cells in a stack can be grouped to store a value for a wordline 111.

Multiplication and accumulation operations of applying weights to inputs can be implemented via programming memory cells in an array (e.g., implemented as in FIG. 1 to FIG. 9) to have states representative of weights. When voltages representative of inputs are applied to wordlines of the array, the programmed memory cells can output currents representative of the results of the inputs multiplied by the respective weights. Bitlines (or local digit lines, or global digit lines) of the array can collect and sum the output currents. Analog to digital converters can be used to measure the magnitudes of currents in the bitlines (or local digit lines, or global digit lines) and generate digital outputs representative of the results of the multiplication and accumulation operations.

The sum of the products between a list of weights and a respective list of inputs can be configured as the sum of the results from time-sliced computations. Each result from the time-sliced computation can provide a partial sum of the products between a list of weights and a respective list of inputs. Adding the partial sums can provide the sum of the products between the list of weights and the respective list of inputs.

For example, the bits of the inputs can be divided into slices according to bit significance. Each slice can include one or more bits of predetermined significant levels from the inputs. Instead of applying an input to a weight, a slice of significant bits from the input can be applied as an input slice to the weight. The bit slices can be applied one at a time to memory cells storing the weights to generate as partial sums, each corresponding to the sum of the products between the list of weights and a respective bit slice shifted according to the significance of the slice. The sum of the products between the list of weights and the respective list of inputs can be obtained from adding, using a digital circuit, the partial sums.

For example, an input pattern can be presented as a digital bit-stream to a memory array storing weights in a serial-parallel manner, where one bit from each input is applied at a time sequentially, and bits from multiple inputs are applied to the memory array in parallel. At each such time slice, the same significant bit level of each input pattern is presented. Also, at each such slice, the multiplication and accumulation operation as applied the weights is carried out to generate a partial sum of products. After all slices have been presented, all partial sums have been computed, which can then be combined by taking into account the significance of each slice to generate the overall sum of products.

FIG. 10 shows the computation of a column of weight bits multiplied by a column of input bits to provide an accumulation result according to one embodiment.

In FIG. 10, a column of synapse unit cells 207, 217, . . . , 227 can be programmed in the synapse mode to have threshold voltages at levels representative of weights stored one bit per memory cell/unit cell.

For example, the column of synapse unit cells 207, 217, . . . , 227 can be implemented using memory cells configured a stack of unit cells (e.g., 101, 103) manufactured in a semiconductive device having a three-dimensional structure as in FIG. 1. For example, each of the unit cells (e.g., 101, 103) in the stack can have a structure as illustrated in FIG. 2, FIG. 3, and/or FIG. 4. For example, the stack of unit cells can have a vertical structure according to FIG. 5. The structure of the stack can be replicated in a direction of wordlines (e.g., X-axis) to have a slice of unit cells having a horizontal structure as in FIG. 6 and FIG. 7. The structure of the slice of unit cells can be replicated in another horizontal structures to form a three-dimensional array of unit cells having a plurality of slices. Optionally, a plurality of unit cells in the stack are used together to store a multi-bit value; and the vertical structure of the stack can be implemented as in FIG. 9.

The column of unit cells 207, 217, . . . , 227, programmed in the synapse mode, can be read in a synapse mode, during which voltage drivers 203, 213, . . . , 223 are configured to apply voltages 205, 215, . . . , 225 concurrently to the unit cells 207, 217, . . . , 227 respectively according to their received input bits 201, 211, . . . , 221.

For example, when the input bit 201 has a value of one, the voltage driver 203 applies the predetermined read voltage as the voltage 205, causing the unit cell 207 to output the predetermined amount of current as its output current 209 if the unit cell 207 has a threshold voltage programmed at a lower level, which is lower than the predetermined read voltage, to represent a stored weight of one, or to output a negligible amount of current as its output current 209 if the unit cell 207 has a threshold voltage programmed at a higher level, which is higher than the predetermined read voltage, to represent a stored weight of zero. However, when the input bit 201 has a value of zero, the voltage driver 203 applies a voltage (e.g., zero) lower than the lower level of threshold voltage as the voltage 205 (e.g., does not apply the predetermined read voltage), causing the unit cell 207 to output a negligible amount of current at its output current 209 regardless of the weight stored in the unit cell 207. Thus, the output current 209 as a multiple of the predetermined amount of current is representative of the result of the weight bit, stored in the unit cell 207, multiplied by the input bit 201.

Similarly, the current 219 going through the unit cell 217 as a multiple of the predetermined amount of current is representative of the result of the weight bit, stored in the unit cell 217, multiplied by the input bit 211; and the current 229 going through the unit cell 227 as a multiple of the predetermined amount of current is representative of the result of the weight bit, stored in the unit cell 227, multiplied by the input bit 221.

The output currents 209, 219, . . . , and 229 of the unit cells 207, 217, . . . , 227 are connected to a common line 241 (e.g., bitline, local digit line 121, global digit line 129) for summation. The summed current 231 is compared to the unit current 232, which is equal to the predetermined amount of current, by a digitizer 233 of an analog to digital converter 245 to determine the digital result 237 of the column of weight bits, stored in the unit cells 207, 217, . . . , 227 respectively, multiplied by the column of input bits 201, 211, . . . , 221 respectively with the summation of the results of multiplications.

The sum of negligible amounts of currents from unit cells connected to the line 241 is small when compared to the unit current 232 (e.g., the predetermined amount of current). Thus, the presence of the negligible amounts of currents from unit cells does not alter the result 237 and is negligible in the operation of the analog to digital converter 245.

In FIG. 10, the voltages 205, 215, . . . , 225 applied to the unit cells 207, 217, 227 are representative of digitized input bits 201, 211, . . . , 221; the unit cells 207, 217, . . . , 227 are programmed to store digitized weight bits; and the currents 209, 219, . . . , 229 are representative of digitized results. Thus, the unit cells 207, 217, . . . , 227 do not function as memristors that convert analog voltages to analog currents based on their linear resistances over a voltage range; and the operating principle of the unit cells in computing the multiplication is fundamentally different from the operating principle of a memristor crossbar. When a memristor crossbar is used, conventional digital to analog converters are used to generate an input voltage proportional to inputs to be applied to the rows of memristor crossbar. When the technique of FIG. 10 is used, such digital to analog converters can be eliminated; and the operation of the digitizer 233 to generate the result 237 can be greatly simplified. The result 237 is an integer that is no larger than the count of unit cells 207, 217, . . . , 227 connected to the line 241. The digitized form of the output currents 209, 219, . . . , 229 can increase the accuracy and reliability of the computation implemented using the unit cells 207, 217, . . . , 227.

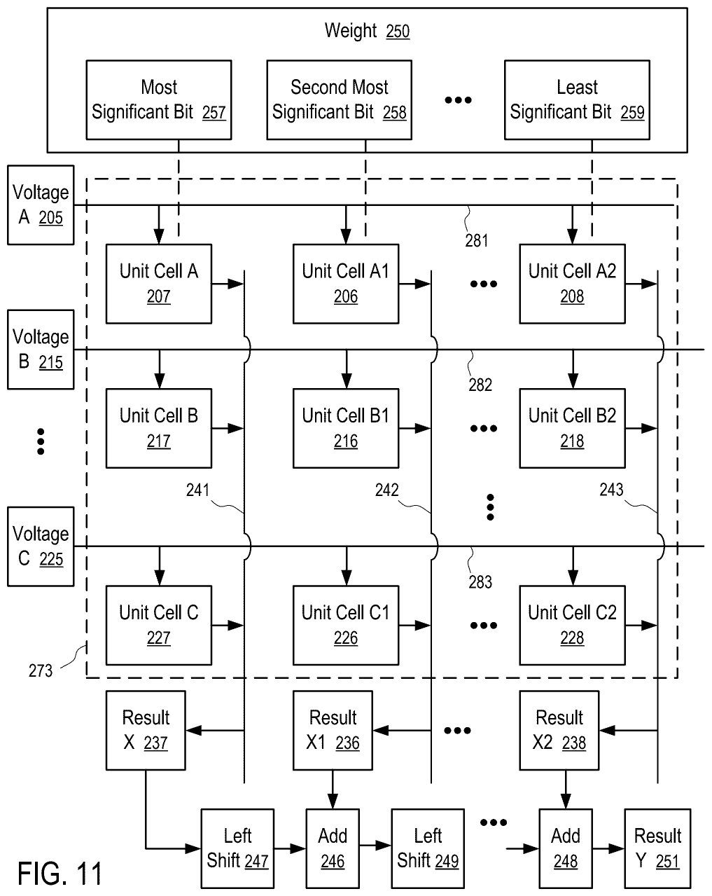

In general, a weight involving a multiplication and accumulation operation can be more than one bit. Multiple columns of unit cells can be used to store the different significant bits of weights, as illustrated in FIG. 11 to perform multiplication and accumulation operations.

The circuit illustrated in FIG. 10 can be considered a multiplier-accumulator unit configured to operate on a column of 1-bit weights and a column of 1-bit inputs. Multiple such circuits can be connected in parallel to implement a multiplier-accumulator unit to operate on a column of multi-bit weights and a column of 1-bit inputs, as illustrated in FIG. 11.

The circuit illustrated in FIG. 10 can also be used to read the data stored in the unit cells 207, 217, . . . , 227. For example, to read the data or weight stored in the unit cell 207, the input bits 211, . . . , 221 can be set to zero to cause the unit cells 217, . . . 227 to output negligible amount of currents into the line 241 (e.g., as a bitline). The input bit 201 is set to one to cause the voltage driver 203 to apply the predetermined read voltage. Thus, the result 237 from the digitizer 233 provides the data or weight stored in the unit cell 207. Similarly, the data or weight stored in the unit cell 217 can be read via applying one as the input bit 211 and zeros as the remaining input bits in the column; and data or weight stored in the unit cell 227 can be read via applying one as the input bit 221 and zeros as the other input bits in the column.

In general, the circuit illustrated in FIG. 10 can be used to select any of the unit cells 207, 217, . . . , 227 for read or write. A voltage driver (e.g., 203) can apply a programming voltage pulse to adjust the threshold voltage of the memory cell in a respective unit cell (e.g., 207) to erase data, to store data or weigh, etc.

FIG. 11 shows the computation of a column of multi-bit weights multiplied by a column of input bits to provide an accumulation result according to one embodiment.

In FIG. 11, a weight 250 in a binary form has a most significant bit 257, a second most significant bit 258, . . . , a least significant bit 259. The significant bits 257, 258, . . . , 259 can be stored in a row of unit cells 207, 206, . . . , 208 (e.g., in the unit cell array of an analog computing module) across a number of columns respectively in an array 273. The significant bits 257, 258, . . . , 259 of the weight 250 are to be multiplied by the input bit 201 represented by the voltage 205 applied on a line 281 (e.g., a wordline) by a voltage driver 203 (e.g., as in FIG. 10).

For example, the row of unit cells 207, 206, . . . , 208 can be implemented as a row of unit cells (e.g., 101, 151, 153 as in FIG. 6) connected to a same wordline (e.g., 111 as in FIG. 6) in a slice of a three dimensional array of unit cells as discussed in connection with in FIG. 1 to FIG. 9.

For example, the array 273 can be implemented in a slice of unit cells in a three-dimensional array as discussed in connection with FIG. 1 to FIG. 9.

Similarly, unit cells 217, 216, . . . , 218 can be used to store the corresponding significant bits of a next weight to be multiplied by a next input bit 211 represented by the voltage 215 applied on a line 282 (e.g., a wordline) by a voltage driver 213 (e.g., as in FIG. 10); and unit cells 227, 226,., 228 can be used to store corresponding bits of a weight to be multiplied by the input bit 221 represented by the voltage 225 applied on a line 283 (e.g., a wordline) by a voltage driver 223 (e.g., as in FIG. 10).

The most significant bits (e.g., 257) of the weights (e.g., 250) stored in the respective rows in the array 273 are multiplied by the input bits 201, 211, . . . , 221 represented by the voltages 205, 215, . . . , 225 and then summed as the current 231 in a line 241 and digitized using a digitizer 233, as in FIG. 10, to generate a result 237 corresponding to the most significant bits of the weights.

Similarly, the second most significant bits (e.g., 258) of the weights (e.g., 250) stored in the respective rows in the array 273 are multiplied by the input bits 201, 211, . . . , 221 represented by the voltages 205, 215, . . . , 225 and then summed as a current in a line 242 and digitized to generate a result 236 corresponding to the second most significant bits.

Similarly, the least most significant bits (e.g., 259) of the weights (e.g., 250) stored in the respective rows in the array 273 are multiplied by the input bits 201, 211, . . . , 221 represented by the voltages 205, 215, . . . , 225 and then summed as a current in a line 243 and digitized to generate a result 238 corresponding to the least significant bit.

The most significant bit can be left shifted by one bit to have the same weight as the second significant bit, which can be further left shifted by one bit to have the same weight as the next significant bit. Thus, the result 237 generated from multiplication and summation of the most significant bits (e.g., 257) of the weights (e.g., 250) can be applied an operation of left shift 247 by one bit; and the operation of add 246 can be applied to the result of the operation of left shift 247 and the result 236 generated from multiplication and summation of the second most significant bits (e.g., 258) of the weights (e.g., 250). The operations of left shift (e.g., 247, 249) can be used to apply weights of the bits (e.g., 257, 258, . . . ) for summation using the operations of add (e.g., 246, . . . , 248) to generate a result 251. Thus, the result 251 is equal to the column of weights in the array 273 multiplied by the column of input bits 201, 211, . . . , 221 with multiplication results accumulated.

In some implementations, a memory cell/unit cell can be programmed to output a multiple of the unit current 232 when the predetermined voltage is applied, and output a negligible amount of current when the applied voltage is smaller than the predetermined voltage. Thus, a memory cell in a unit cell (e.g., 207) can be programmed to represent the value of a bit of the weight (e.g., 250) and its weight over another unit cell (e.g., 206).

For example, when the most significant bit 257 has a value of one, the unit cell 207 is programmed to have a state such that when the predetermined voltage representative of an input bit 201 having a value of one is applied to the unit cell 207, the unit cell 207 outputs 2 times the unit current, such that the current magnitude of the bitline 241 has a bit weight built in the currents generated by the unit cells 207, 217, . . . , 227. As a result the currents in the bitline 241 and 242 can be connected to a common line for measuring using the same analog to digital converter 245. Such an arrangement can reduce the number of analog to digital converters 245 configured to generate digitized results.

In some implementations, a unit cell (e.g., 207) can be programmed to generate 4 times the unit current when applied the predetermined voltage representative of an input bit 201 having a values of one; and another unit cell (e.g., 206) can be programmed to generate 2 times the unit current when applied the predetermined voltage representative of the input bit 201 having the values of one. Thus, the unit cells 207 and 206 can be programmed to store the most significant bit 257 and the second most significant but 258 with bit weights relative to a further unit cell programmed to store the third most significant bit. Since the currents in the bitlines 241, 242 connected to the unit cells 207 and 206 have built-in bit weights relative to the bitline connected to the further unit cells, the three bitlines can be connected to a common line for accumulation and for measuring using the same analog to digital converter 245. Thus, the number of analog to digital converters 245 configured to generate digitized results can be further reduced. Further, the circuits configured to perform the operations of left shift (e.g., 247) and add (e.g., 246) can be reduced.

In some implementations, a unit cell (e.g., 207) can be programmed to output an amount of current that is a multiple of the unit current 232 corresponding to the value of a bit segment (e.g., 257 and 258) of a weight (e.g., 250). Thus, the unit cell (e.g., 207) can be programmed to store the bit segment and thus reduce the number of unit cells configured to store the weight (e.g., 250).

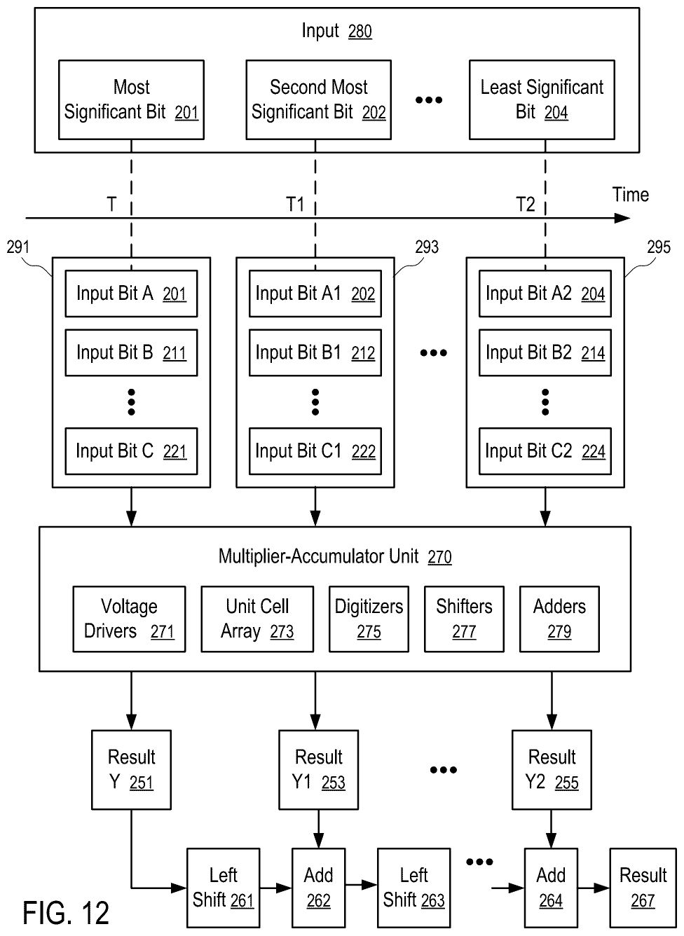

In general, an input involving a multiplication and accumulation operation can be more than one bit. Columns of input bits can be applied one column at a time to the weights stored in the array 273 of unit cells to obtain the result of a column of weights multiplied by a column of inputs with results accumulated as illustrated in FIG. 12.

The circuit illustrated in FIG. 11 can be used to read the data stored in the array 273 of unit cells. For example, to read the data or weight 250 stored in the unit cells 207, 206, . . . , 208, the input bits 211, . . . , 221 can be set to zero to cause the unit cells 217, 216, . . . , 218, . . . , 227, 226, . . . , 228 to output negligible amount of currents into the line 241, 242, . . . , 243 (e.g., as bitlines). The input bit 201 is set to one to cause the voltage driver 203 to apply the predetermined read voltage as the voltage 205. Thus, the results 237, 236, . . . , 238 from the digitizers (e.g., 233) connected to the lines 241, 242, . . . , 243 provide the bits 257, 258, . . . , 259 of the data or weight 250 stored in the row of unit cells 207, 206, . . . , 208. Further, the result 251 computed from the operations of shift 247, 249, . . . and operations of add 246, . . . , 248 provides the weight 250 in a binary form.

In general, the circuit illustrated in FIG. 11 can be used to select any row of the unit cell array 273 for read. Optionally, different columns of the unit cell array 273 can be driven by different voltage drivers. Thus, the unit cells (e.g., 207, 206, . . . , 208) in a row can be programmed to write data in parallel (e.g., to store the bits 257, 258, . . . , 259) of the weight 250.

FIG. 12 shows the computation of a column of multi-bit weights multiplied by a column of multi-bit inputs to provide an accumulation result according to one embodiment.

In FIG. 12, the significant bits of inputs (e.g., 280) are applied to a multiplier-accumulator unit 270 at a plurality of time instances T, T1, . . . , T2.

For example, a multi-bit input 280 can have a most significant bit 201, a second most significant bit 202, . . . , a least significant bit 204.

At time T, an input bit slice 291 having the most significant bits 201, 211, . . . , 221 of the inputs (e.g., 280) can be applied to the multiplier-accumulator unit 270 to obtain a result 251 of weights (e.g., 250), stored in the unit cell array 273, multiplied by the column of bits 201, 211, . . . , 221 with summation of the multiplication results.

For example, the multiplier-accumulator unit 270 can be implemented in a way as illustrated in FIG. 11. The multiplier-accumulator unit 270 has voltage drivers 271 connected to apply voltages 205, 215, . . . , 225 representative of the input bits 201, 211, . . . , 221. The multiplier-accumulator unit 270 has a unit cell array 273 storing bits of weights as in FIG. 11. The multiplier-accumulator unit 270 has digitizers 275 to convert currents summed on lines 241, 242, . . . , 243 for columns in the array 273 to output results 237, 236, . . . , 238. The multiplier-accumulator unit 270 has shifters 277 and adders 279 connected to combine the column result 237, 236, . . . , 238 to provide a result 251 as in FIG. 11. In some implementations, the logic circuits of the multiplier-accumulator unit 270 (e.g., shifters 277 and adders 279) are implemented as part of the inference logic circuit of an analog computing module.

Similarly, at time T1, an input bit slice 293 having the second most significant bits 202, 212, . . . , 222 of the inputs (e.g., 280) can be applied to the multiplier-accumulator unit 270 to obtain a result 253 of weights (e.g., 250) stored in the unit cell array 273 and multiplied by the vector of bits 202, 212, . . . , 222 with summation of the multiplication results.

Similarly, at time T2, an input bit slice 295 having the least significant bits 204, 214, . . . , 224 of the inputs (e.g., 280) can be applied to the multiplier-accumulator unit 270 to obtain a result 255 of weights (e.g., 250), stored in the unit cell array 273, multiplied by the vector of bits 202, 212, . . . , 222 with summation of the multiplication results.

The result 251 generated from multiplication and summation of the most significant bits 201, 211, . . . , 221 of the inputs (e.g., 280) can be applied an operation of left shift 261 by one bit; and the operation of add 262 can be applied to the result of the operation of left shift 261 and the result 253 generated from multiplication and summation of the second most significant bits 202, 212, . . . , 222 of the inputs (e.g., 280). The operations of left shift (e.g., 261, 263) can be used to apply weights of the bits (e.g., 201, 202, . . . ) for summation using the operations of add (e.g., 262, . . . , 264) to generate a result 267. Thus, the result 267 is equal to the weights (e.g., 250) in the array 273 multiplied by the column of inputs (e.g., 280) respectively and then summed.

In some implementations, a current accumulator (e.g., a capacitor) is configured on a bitline (e.g., 241) to generate a parameter that is the integration of the bitline current over a time period. The time period can be configured according to a bit weight of a significant bit (e.g., 201). An analog to digital converter can be configured to measure the parameter generated using the current accumulator.

Optionally, the current generated in a bitline (e.g., 241) for successive bit slices (e.g., 291 and 293) can be accumulated in the current accumulator for measuring in one operation. Thus, the successive bit slices (e.g., 291 and 293) can be combined and viewed as one bit slice.

A plurality of multiplier-accumulator unit 270 can be connected in parallel to operate on a matrix of weights multiplied by a column of multi-bit inputs over a series of time instances T, T1, . . . , T2.

FIG. 10 to FIG. 12 illustrate the multiplication and accumulation computation implemented using unit cells in an array 273 where each unit cell (e.g., 207, 206, or 208) is programmed to store one significant bit (e.g., 257, 258, or 259) of a weight (e.g., 250).

Optionally, a plurality of unit cells in a stack can be combined to store multiple significant bits of a weight. For example, three unit cells in a stack can be grouped and programmed to store a 2-bit value. When the 2-bit value is three, each of the three unit cells in the group is programmed to store a value of one, such that when the wordline connected to the unit cells has a voltage representing one, the total current going through the three unit cells is three times the predetermined amount of current. When the 2-bit value is two, two of the three unit cells in the group are each programmed to store a value of one, with the other unit cell storing a value of zero, such that when the wordline connected to the unit cells has a voltage representing one, the total current going through the three memory cells is two times the predetermined amount of current. When the 2-bit value is one, one of the three unit cells in the group is programmed to store a value of one, with the other two unit cells each storing a value of zero, such that when the wordline connected to the unit cells has a voltage representing one, the total current going through the three unit cells is the predetermined amount of current. When the 2-bit value is zero, each of the three unit cells in the group is programmed to store a value of zero, such that when the wordline connected to the unit cells has a voltage representing one, the total current going through the three unit cells is negligible.

Optionally, each unit cell in a stack can be programmed to store a multi-bit value such that when the wordline connected to the memory cell has a voltage representing one, the current going through the unit cell is substantially equal to the multi-bit value times the predetermined amount of current.

FIG. 3 and FIG. 4 illustrate a unit cell implemented via a phase-change material 145. The phase-change material 145 (e.g., chalcogenide glass) can have a high-conductive crystalline phase and a low-conductive amorphous phase. The resistance of the phase-change material 145 configured in a unit cell can be adjusted/programmed via applying voltage/current pulses. In general, alternatively memory cells can be used in a unit cell 101 in a three-dimensional array having a structure similar to those illustrated in FIG. 1, FIG. 2, FIG. 5 to FIG. 7, and/or FIG. 9, and used to perform multiplication and accumulation operations as discussed above in connection with FIG. 10 to FIG. 12.

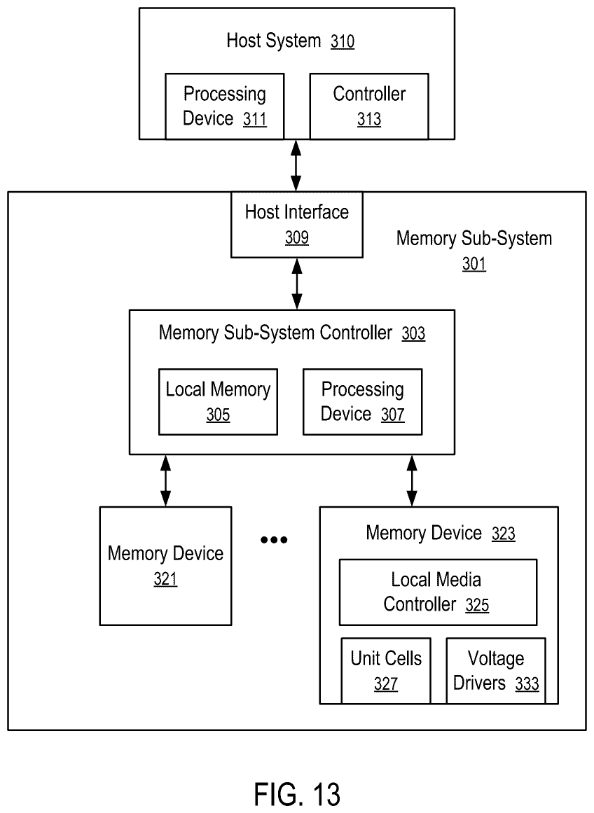

FIG. 13 shows an example computing system having a memory sub-system configured to perform multiplication and accumulation operations according to one embodiment.

The example computing system of FIG. 13 includes a host system 310 and a memory sub-system 301. An analog compute module (e.g., having the unit cells implemented using a three-dimensional array of unit cells as discussed in connection with FIG. 1 to FIG. 9) can be configured in the memory sub-system 301, or in the host system 310.

The memory sub-system 301 can include media, such as one or more volatile memory devices (e.g., memory device 321), one or more non-volatile memory devices (e.g., memory device 323), or a combination of such.

For example, the memory device 323 can include unit cells 327 configured to store weights (e.g., as unit cells in the array 273 in FIG. 11). The memory device 323 can include voltage drivers 333 configured to apply input bit slices as the voltage drivers 203, 213, . . . , 223 in FIG. 10, or voltage drivers 271 as in FIG. 12. The memory device 323 can include analog to digital converters (e.g., 245).

A memory sub-system 301 can be a storage device, a memory module, or a hybrid of a storage device and memory module. Examples of a storage device include a solid-state drive (SSD), a flash drive, a universal serial bus (USB) flash drive, an embedded multi-media controller (eMMC) drive, a universal flash storage (UFS) drive, a secure digital (SD) card, and a hard disk drive (HDD). Examples of memory modules include a dual in-line memory module (DIMM), a small outline DIMM (SO-DIMM), and various types of non-volatile dual in-line memory module (NVDIMM).

The computing system can be a computing device such as a desktop computer, a laptop computer, a network server, a mobile device, a vehicle (e.g., airplane, drone, train, automobile, or other conveyance), an internet of things (IoT) enabled device, an embedded computer (e.g., one included in a vehicle, industrial equipment, or a networked commercial device), or such a computing device that includes memory and a processing device.

The computing system can include a host system 310 that is coupled to one or more memory sub-systems 301. FIG. 13 illustrates one example of a host system 310 coupled to one memory sub-system 301. As used herein, “coupled to” or “coupled with” generally refers to a connection between components, which can be an indirect communicative connection or direct communicative connection (e.g., without intervening components), whether wired or wireless, including connections such as electrical, optical, magnetic, etc.

The host system 310 can include a processor chipset (e.g., processing device 311) and a software stack executed by the processor chipset. The processor chipset can include one or more cores, one or more caches, a memory controller (e.g., controller 313) (e.g., NVDIMM controller), and a storage protocol controller (e.g., PCIe controller, SATA controller). The host system 310 uses the memory sub-system 301, for example, to write data to the memory sub-system 301 and read data from the memory sub-system 301.

The host system 310 can be coupled to the memory sub-system 301 via a physical host interface 309. Examples of a physical host interface 309 include, but are not limited to, a serial advanced technology attachment (SATA) interface, a peripheral component interconnect express (PCIe) interface, a universal serial bus (USB) interface, a fibre channel, a serial attached SCSI (SAS) interface, a double data rate (DDR) memory bus interface, a small computer system interface (SCSI), a dual in-line memory module (DIMM) interface (e.g., DIMM socket interface that supports double data rate (DDR)), an open NAND flash interface (ONFI), a double data rate (DDR) interface, a low power double data rate (LPDDR) interface, or any other interface. The physical host interface 309 can be used to transmit data between the host system 310 and the memory sub-system 301. The host system 310 can further utilize an NVM express (NVMe) interface to access components (e.g., memory devices 323) when the memory sub-system 301 is coupled with the host system 310 by the PCIe interface. The physical host interface 309 can provide an interface for passing control, address, data, and other signals between the memory sub-system 301 and the host system 310. FIG. 13 illustrates a memory sub-system 301 as an example. In general, the host system 310 can access multiple memory sub-systems via a same communication connection, multiple separate communication connections, and/or a combination of communication connections.

The processing device 311 of the host system 310 can be, for example, a microprocessor, a central processing unit (CPU), a processing core of a processor, an execution unit, etc. In some instances, the controller 313 can be referred to as a memory controller, a memory management unit, and/or an initiator. In one example, the controller 313 controls the communications over a bus coupled between the host system 310 and the memory sub-system 301. In general, the controller 313 can send commands or requests to the memory sub-system 301 for desired access to memory devices 323, 321. The controller 313 can further include interface circuitry to communicate with the memory sub-system 301. The interface circuitry can convert responses received from the memory sub-system 301 into information for the host system 310.

The controller 313 of the host system 310 can communicate with the controller 303 of the memory sub-system 301 to perform operations such as reading data, writing data, or erasing data at the memory devices 323, 321 and other such operations. In some instances, the controller 313 is integrated within the same package of the processing device 311. In other instances, the controller 313 is separate from the package of the processing device 311. The controller 313 and/or the processing device 311 can include hardware such as one or more integrated circuits (ICs) and/or discrete components, a buffer memory, a cache memory, or a combination thereof. The controller 313 and/or the processing device 311 can be a microcontroller, special purpose logic circuitry (e.g., a field programmable gate array (FPGA), an application specific integrated circuit (ASIC), etc.), or another suitable processor.

The memory devices 323, 321 can include any combination of the different types of non-volatile memory components and/or volatile memory components. The volatile memory devices (e.g., memory device 321) can be, but are not limited to, random access memory (RAM), such as dynamic random access memory (DRAM) and synchronous dynamic random access memory (SDRAM).

Some examples of non-volatile memory components include a negative-and (or, NOT AND) (NAND) type flash memory and write-in-place memory, such as three-dimensional cross-point (“3D cross-point”) memory. A cross-point array of non-volatile memory can perform bit storage based on a change of bulk resistance, in conjunction with a stackable cross-gridded data access array. Additionally, in contrast to many flash-based memories, cross-point non-volatile memory can perform a write in-place operation, where a non-volatile memory cell can be programmed without the non-volatile memory cell being previously erased. NAND type flash memory includes, for example, two-dimensional NAND (2D NAND) and three-dimensional NAND (3D NAND).

Each of the memory devices 323 can include one or more arrays of memory cells. One type of memory cell, for example, single level cells (SLC) can store one bit per cell. Other types of memory cells, such as multi-level cells (MLCs), triple level cells (TLCs), quad-level cells (QLCs), and penta-level cells (PLCs) can store multiple bits per cell. In some embodiments, each of the memory devices 323 can include one or more arrays of memory cells such as SLCs, MLCs, TLCs, QLCs, PLCs, or any combination of such. In some embodiments, a particular memory device can include an SLC portion, an MLC portion, a TLC portion, a QLC portion, and/or a PLC portion of memory cells. The memory cells of the memory devices 323 can be grouped as pages that can refer to a logical unit of the memory device used to store data. With some types of memory (e.g., NAND), pages can be grouped to form blocks.

Although non-volatile memory devices such as 3D cross-point type and NAND type memory (e.g., 2D NAND, 3D NAND) are described, the memory device 323 can be based on any other type of non-volatile memory, such as read-only memory (ROM), phase-change memory (PCM), self-selecting memory, other chalcogenide based memories, ferroelectric transistor random-access memory (FeTRAM), ferroelectric random access memory (FeRAM), magneto random access memory (MRAM), spin transfer torque (STT)-MRAM, conductive bridging RAM (CBRAM), resistive random access memory (RRAM), oxide based RRAM (OxRAM), negative-or (NOR) flash memory, and electrically erasable programmable read-only memory (EEPROM).

A memory sub-system controller 303 (or controller 303 for simplicity) can communicate with the memory devices 323 to perform operations such as reading data, writing data, or erasing data at the memory devices 323 and other such operations (e.g., in response to commands scheduled on a command bus by controller 313). The controller 303 can include hardware such as one or more integrated circuits (ICs) and/or discrete components, a buffer memory, or a combination thereof. The hardware can include digital circuitry with dedicated (i.e., hard-coded) logic to perform the operations described herein. The controller 303 can be a microcontroller, special purpose logic circuitry (e.g., a field programmable gate array (FPGA), an application specific integrated circuit (ASIC), etc.), or another suitable processor.

The controller 303 can include a processing device 307 (processor) configured to execute instructions stored in a local memory 305. In the illustrated example, the local memory 305 of the controller 303 includes an embedded memory configured to store instructions for performing various processes, operations, logic flows, and routines that control operation of the memory sub-system 301, including handling communications between the memory sub-system 301 and the host system 310.

In some embodiments, the local memory 305 can include memory registers storing memory pointers, fetched data, etc. The local memory 305 can also include read-only memory (ROM) for storing micro-code. While the example memory sub-system 301 in FIG. 13 has been illustrated as including the controller 303, in another embodiment of the present disclosure, a memory sub-system 301 does not include a controller 303, and can instead rely upon external control (e.g., provided by an external host, or by a processor or controller separate from the memory sub-system).

In general, the controller 303 can receive commands or operations from the host system 310 and can convert the commands or operations into instructions or appropriate commands to achieve the desired access to the memory devices 323. The controller 303 can be responsible for other operations such as wear leveling operations, garbage collection operations, error detection and error-correcting code (ECC) operations, encryption operations, caching operations, and address translations between a logical address (e.g., logical block address (LBA), namespace) and a physical address (e.g., physical block address) that are associated with the memory devices 323. The controller 303 can further include host interface circuitry to communicate with the host system 310 via the physical host interface. The host interface circuitry can convert the commands received from the host system into command instructions to access the memory devices 323 as well as convert responses associated with the memory devices 323 into information for the host system 310.

The memory sub-system 301 can also include additional circuitry or components that are not illustrated. In some embodiments, the memory sub-system 301 can include a cache or buffer (e.g., DRAM) and address circuitry (e.g., a row decoder and a column decoder) that can receive an address from the controller 303 and decode the address to access the memory devices 323.

In some embodiments, the memory devices 323 include local media controllers 325 that operate in conjunction with the memory sub-system controller 303 to execute operations on one or more memory cells of the memory devices 323. An external controller (e.g., memory sub-system controller 303) can externally manage the memory device 323 (e.g., perform media management operations on the memory device 323). In some embodiments, a memory device 323 is a managed memory device, which is a raw memory device combined with a local controller (e.g., local media controller 325) for media management within the same memory device package. An example of a managed memory device is a managed NAND (MNAND) device.

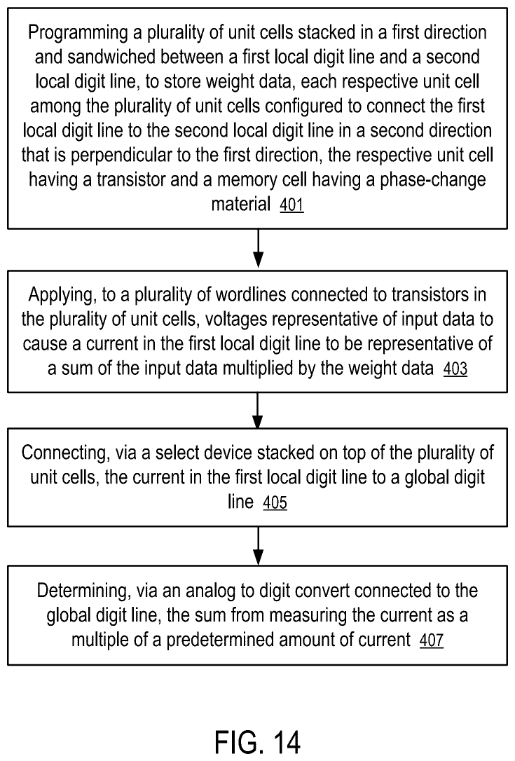

FIG. 14 shows a method to perform operations of multiplication and accumulation according to one embodiment. For example, the method can be implemented in a computing system or device of FIG. 13 with unit cells having a three-dimensional structure as in FIG. 1 to FIG. 7 and/or FIG. 9 and the computing techniques discussed in connection with FIG. 10 to FIG. 12.

At block 401, the method includes programming a plurality of unit cells (e.g., 101, 103) to store weight data (e.g., 250). The plurality of unit cells (e.g., 101, 103) can be stacked in a first direction (e.g., Z-axis) and sandwiched in a second direction (e.g., Y-axis) between a first local digit line (e.g., 121) and a second local digit line (e.g., 123).

For example, each respective unit cell (e.g., 101) among the plurality of unit cells (e.g., 101, 103) is configured to connect the first local digit line (e.g., 121) to the second local digit line (e.g., 123) in a second direction (e.g., Y-axis) that is perpendicular to the first direction (e.g., Z-axis), as in FIG. 1. For example, each respective unit cell (e.g., 101) is configured to have a single transistor (e.g., 131) and a single memory cell (e.g., 132), as in FIG. 2. The memory cell (e.g., 132) can be implemented using a phase-change material 145.

For example, the plurality of unit cells (e.g., 101, 103) can be stacked in the first direction (e.g., Z-axis) to provide a stack of memory cells (e.g., 132, 134). A three-dimensional array of unit cells can be formed by replicating the structure of the stack of unit cells (e.g., 101, 103) in a third direction (e.g., X-axis), to have a slice of unit cells in the three-dimensional array, as illustrated in FIG. 6 and FIG. 7. Such a slice can be replicated in the second direction (e.g., Y-axis) to form a plurality of slices in the three-dimensional array.

For example, the memory cell 132 in the respective unit cell 101 can include two ionic liquid layers 143 and 147. The phase-change material 145 of the memory cell 132 can be sandwiched between the two ionic liquid layers 143 and 147, as illustrated in FIG. 3 and FIG. 4. Further, the memory cell 132 can include two metal layers 141 and 149; and the two ionic liquid layers 143 and 149, and the phase-change material 145 between them, are sandwiched between the two metal layers 141 and 149.

Optionally, the selector transistor 131 is implemented using a channel of a first type, where the channel is configured to extend in the second direction (e.g., Y-axis) from (and in contact with) the first local digit line 121 to one metal layer 141 of the memory cell 132. The other metal layer 149 of the memory cell 132 is in contact with the second digit line 123. Further, the selector transistor 131 is implemented using two channels of a second type, where the channel of the first type and the memory cell 132 are sandwiched between the two channels of the second type, with isolation material 135 separating the two channels of the second type from the metal layers 141, 149, the ionic liquid layers 143 and 147, and the phase-change material 145 of the memory cell 132, as illustrated in FIG. 4. The two channels of the second type form a gate of the transistor 131.

FIG. 4 illustrates an example where the channel of the first type is an N-channel, and the two channels of the second type are P-channels. Alternatively, the channel of the first type can be a P-channel and the two channels of the second type can be N-channels.

As in FIG. 1 to FIG. 5 and FIG. 9, the first local digit line 121 and the second local digit line 123 are configured to extend, in the three dimensional array, in the first direction (e.g., Z-axis) that is perpendicular to the second direction (e.g., Y-axis) and the third direction (e.g., X-axis). The plurality of unit cells (e.g., 101, 103) stacked in the first direction (e.g., Z-axis) in the array are sandwiched between, and electrically connected to, the first local digit line 121 and the second local digit line 123.

As in FIG. 3 and FIG. 4, the metal layers 141, the ionic liquid layers 147, and the phase-change material 145 of the memory cell 132 can be stacked in the second direction (e.g., Y-axis).

Optionally, a common plate 120 can be configured at the bottom of the three-dimension array of unit cells. For example, the unit cells (e.g., 101, 103) in the array can be stacked in the first direction (e.g., Z-axis) over the common plate 120; the second local digit line 123 of each stack of unit cells (e.g., 101, 103) extends in the first direction (e.g., Z-axis) to be in contact with the common plate 120.

A plurality of wordlines (e.g., 111, 113) can be configured within the array and connected to the gates of the transistors of unit cells in slices. Each wordline (e.g., 111) can extend in the third direction (e.g., X-axis) that is perpendicular to the first direction (e.g., Z-axis) of stacking of unit cells, and the second direction (e.g., Y-axis) of stacking layers of each memory cell (e.g., 132).

As in FIG. 5, each of the two channels of the second type (e.g., P-channels 144) of a unit cell (e.g., 101) is connected to one of the wordlines (e.g., 111). Two wordlines (e.g., 111) carrying the same signal can be configured above and below a unit cell (e.g., 101) for connection to the two channels of the second type (e.g., P-channels 144).

Optionally, as in FIG. 5 and FIG. 9, a select device (e.g., 109) can be stacked on top of each stack of unit cells (e.g., 101, 103) and connected between the first local digit line (e.g., 121) and a global digit line (e.g., 129). A control line (e.g., 119) connected to the select device (e.g., 109) in a way similar to a wordline (e.g., 111) being connected to a unit cell (e.g., 101). The select device 109 can be formed to have a transistor in a way similar to a unit cell (e.g., 101) but without a memory cell. For example, the select device 109 is sandwiched between the first local digit line 121 and the global digit line 129 in a way similar to the unit cell being sandwiched between the first local digit line 121 and the second local digit line 123; and the channel of the first type of the transistor in the select device 109 can extend from the first local digit line 121 to the global digit line 129 with a memory cell.

At block 403, the method further includes applying, to a plurality of wordlines (e.g., 111, 113) connected to transistors in the plurality of unit cells (e.g., 101, 103), voltages (e.g., 205, 215) representative of input data to cause a current in the first local digit line (e.g., 121) to be representative of a sum of the input data multiplied by the weight data.

For example, the voltages on wordline lines (e.g., 111, 113) can be applied in a way as illustrated in FIG. 11 on wordlines 281, 282, . . . , 283, when a column of memory cells (e.g., 207, 217, . . . ) in the array 273 of FIG. 11 is implemented using the memory cells (e.g., 132, 134, . . . ) in the stack of unit cells (e.g., 101, 103) (e.g., as in FIG. 1, FIG. 5, FIG. 8, and/or FIG. 9).

At block 405, the method further includes connecting, via a select device (e.g., 109) stacked on top of the plurality of unit cells (e.g., 101, 103, . . . ), the current in the first local digit line 121 to a global digit line 129.

At block 407, the method further includes determining, via an analog to digital converter (e.g., 245) connected to the global digit line 129, the sum from measuring the current as a multiple of a predetermined amount of current (e.g., 232).

For example, the memory cell (e.g., 132) in the respective unit cell (e.g., 101 in FIG. 1 implementing unit cell 207 in FIG. 10 and FIG. 11) can be programmed to allow a first amount of current to pass through the respective unit cell (e.g., 101) when a voltage (e.g., 205) applied on a wordline (e.g., 111 in FIG. 1 implementing wordline 281 in FIG. 11) connected to a gate of the transistor (e.g., 131) has a level representative of a bit value of one. The level of the voltage (e.g., 205) representative of a bit value of one is configured to turn on the transistor (e.g., 131); and the first amount is configured/programmed to be substantially equal to the predetermined amount of current (e.g., 232) multiplied by a weight value stored in the memory cell (e.g., 132). When the level of the voltage (e.g., 205) is configured to represent a bit value of zero, the transistor (e.g., 131) is turned off; and an insignificant amount of current goes through the unit cell (e.g., 101). When the levels of the voltage (e.g., 205) are applied in such a way as described above, and the memory cell (e.g., 132) is programmed in such a way as described above, the amount of the current going through the unit cell (e.g., 101) can be representative of the result of multiplication of the bit value represented by the voltage 205 and the weight data stored in the unit cell; and the currents from different unit cells (e.g., 101, 103) in the stack are summed in an analog form in the local digit line (e.g., 121 in FIG. 1 implementing the line 241 in FIG. 10 and FIG. 11).

Optionally, the weight value is a multi-bit value. Alternatively, each memory cell (e.g., 132) is programmed to store a one-bit weight value.

Optionally, the plurality of unit cells (e.g., 101, 103) in a stack can be configured as a plurality of groups of unit cells; transistors in each respective group, among the plurality groups, are configured to be applied a same voltage representative of a same bit of data in the input data; and memory cells in the respective group are combined to store a multi-bit value, while each memory cell in the respective group is programmed to store a one-bit value.

Optionally, each of the unit cells (e.g., 101, 103) in a stack can be separated from other unit cells via a dielectric region 110, as in FIG. 5. A circuitry outside of the three-dimensional array can be used to apply the same voltage representative of the same bit of data to wordlines connected to the unit cells in the respective group.

Alternatively, one or more dielectric regions are positioned between a plurality of pre-configured groups of unit cells in the stack. As illustrated in FIG. 9, unit cells (e.g., 101, 103) with the respective group are not separated via dielectric regions; and adjacent unit cells (e.g., 101 and 103) can be configured to be in contact with a same wordline (e.g., 111). For example, a wordline 111 in a layer can be sandwiched between two layers/planes of unit cells (e.g., 101 and 103).

In one embodiment, an example machine of a computer system within which a set of instructions, for causing the machine to perform any one or more of the methods discussed herein, can be executed. In some embodiments, the computer system can correspond to a host system that includes, is coupled to, or utilizes a memory sub-system or can be used to perform the operations described above. In alternative embodiments, the machine can be connected (e.g., networked) to other machines in a LAN, an intranet, an extranet, or the internet, or any combination thereof. The machine can operate in the capacity of a server or a client machine in client-server network environment, as a peer machine in a peer-to-peer (or distributed) network environment, or as a server or a client machine in a cloud computing infrastructure or environment.

The machine can be a personal computer (PC), a tablet PC, a set-top box (STB), a personal digital assistant (PDA), a cellular telephone, a web appliance, a server, a network router, a switch or bridge, a network-attached storage facility, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system includes a processing device, a main memory (e.g., read-only memory (ROM), flash memory, dynamic random access memory (DRAM) such as synchronous DRAM (SDRAM) or Rambus DRAM (RDRAM), static random access memory (SRAM), etc.), and a data storage system, which communicate with each other via a bus (which can include multiple buses).

Processing device represents one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. Processing device can also be one or more special-purpose processing devices such as an application specific integrated circuit (ASIC), a field programmable gate array (FPGA), a digital signal processor (DSP), network processor, or the like. The processing device is configured to execute instructions for performing the operations and steps discussed herein. The computer system can further include a network interface device to communicate over the network.

The data storage system can include a machine-readable medium (also known as a computer-readable medium) on which is stored one or more sets of instructions or software embodying any one or more of the methodologies or functions described herein. The instructions can also reside, completely or at least partially, within the main memory and within the processing device during execution thereof by the computer system, the main memory and the processing device also constituting machine-readable storage media. The machine-readable medium, data storage system, or main memory can correspond to the memory sub-system.

In one embodiment, the instructions include instructions to implement functionality corresponding to the operations described above. While the machine-readable medium is shown in an example embodiment to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to convey the substance of their work most effectively to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general-purpose computer selectively activated or reconfigured by a computer program stored in the computer. Such a computer program can be stored in a computer readable storage medium, such as, but not limited to, any type of disk including floppy disks, optical disks, CD-ROMs, and magnetic-optical disks, read-only memories (ROMs), random access memories (RAMs), EPROMs, EEPROMs, magnetic or optical cards, or any type of media suitable for storing electronic instructions, each coupled to a computer system bus.

The algorithms and displays presented herein are not inherently related to any particular computer or other apparatus. Various general-purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium having stored thereon instructions, which can be used to program a computer system (or other electronic devices) to perform a process according to the present disclosure. A machine-readable medium includes any mechanism for storing information in a form readable by a machine (e.g., a computer). In some embodiments, a machine-readable (e.g., computer-readable) medium includes a machine (e.g., a computer) readable storage medium such as a read only memory (“ROM”), random access memory (“RAM”), magnetic disk storage media, optical storage media, flash memory components, etc.

In this description, various functions and operations are described as being performed by or caused by computer instructions to simplify description. However, those skilled in the art will recognize what is meant by such expressions is that the functions result from execution of the computer instructions by one or more controllers or processors, such as a microprocessor. Alternatively, or in combination, the functions and operations can be implemented using special-purpose circuitry, with or without software instructions, such as using application-specific integrated circuit (ASIC) or field-programmable gate array (FPGA). Embodiments can be implemented using hardwired circuitry without software instructions, or in combination with software instructions. Thus, the techniques are limited neither to any specific combination of hardware circuitry and software, nor to any particular source for the instructions executed by the data processing system.

In the foregoing specification, embodiments of the disclosure have been described with reference to specific example embodiments thereof. It will be evident that various modifications can be made thereto without departing from the broader spirit and scope of embodiments of the disclosure as set forth in the following claims. The specification and drawings are, accordingly, to be regarded in an illustrative sense rather than a restrictive sense.

What is claimed is:

1. A memory device, comprising:
a three-dimensional array of unit cells, each respective unit cell in the array having a selector transistor and a memory cell having a phase-change material.

2. The memory device of claim 1, wherein the respective unit cell further includes two ionic liquid layers; and the phase-change material is sandwiched between the two ionic liquid layers.

3. The memory device of claim 2, wherein the respective unit cell further includes two metal layers; and the two ionic liquid layers are sandwiched between the two metal layers.

4. The memory device of claim 3, wherein the selector transistor includes:
a channel of a first type of material sandwich between two regions of a second type of material, the channel extending in a second direction to be in contact with one of the two metal layers of the memory cell.

5. The memory device of claim 4, further comprising:
a first local digit line extending in a first direction that is perpendicular to the second direction;
wherein a plurality of unit cells in the array are stacked in the first direction and connected to the first local digit line; and
wherein the channel of a selector transistor of each unit cell in the plurality of unit cells extends in the second direction to be in contact with the first local digit line.

6. The memory device of claim 5, wherein the first type is a P type of semiconductive material; and the second type is an N type of semiconductive material.

7. The memory device of claim 6, wherein the two metal layers, the two ionic liquid layers, and the phase-change material are stacked in the second direction.

8. The memory device of claim 7, further comprising:
a second local digit line extending in the first direction that is perpendicular to the second direction;
wherein one of the two metal layers of a memory cell of each unit cell in the plurality of unit cells is in contact with the second local digit line.

9. The memory device of claim 8, further comprising:
a common plate, wherein the plurality of unit cells in the array are stacked in the first direction over the common plate, and the second local digit line extends in the first direction to be in contact with the common plate.

10. The memory device of claim 9, further comprising:
a plurality of wordlines, each extending in a third direction that is perpendicular to the first direction and the second direction.

11. The memory device of claim 10, further comprising:
a select device stacked on top of the plurality of unit cells and connected between the first local digit line and a global digit line.

12. An apparatus, comprising:
a first local digit line configured to extend in a first direction;
a second local digit line configured in parallel with the first local digit line;
a plurality of unit cells stacked in the first direction and sandwiched between the first local digit line and the second local digit line, each respective unit cell among the plurality of unit cells configured to connect the first local digit line to the second local digit line in a second direction that is perpendicular to the first direction, the respective unit cell having a transistor and a memory cell; and
a plurality of wordlines configured to extend in a third direction that is perpendicular to the first direction and the second direction, wherein transistors in the plurality of unit cells are connected to the wordlines.

13. The apparatus of claim 12, wherein the memory cell includes:
a first metal layer;
a first iconic liquid layer on the first metal layer;
a layer of phase-change material on the first iconic liquid layer;
a second iconic liquid layer on the layer of phase-change material; and
a second metal layer on the second iconic liquid layer.

14. The apparatus of claim 13, wherein the first metal layer, the first iconic liquid layer, the layer of the phase-change material, the second iconic liquid layer, and the second metal layer are stacked in the second direction.

15. The apparatus of claim 14, further comprising:
one or more dielectric regions positioned between a plurality of groups of unit cells in the plurality of unit cells;
wherein each respective group of the plurality of groups has multiple unit cells that are not separated by a dielectric region.

16. The apparatus of claim 15, wherein adjacent unit cells in the respective group are connected to a same wordline among the plurality of wordlines.

17. A method, comprising:
programming a plurality of unit cells stacked in a first direction and sandwiched between a first local digit line and a second local digit line, to store weight data, each respective unit cell among the plurality of unit cells configured to connect the first local digit line to the second local digit line in a second direction that is perpendicular to the first direction, the respective unit cell having a transistor and a memory cell having a phase-change material;
applying, to a plurality of wordlines connected to transistors in the plurality of unit cells, voltages representative of input data to cause a current in the first local digit line to be representative of a sum of the input data multiplied by the weight data;
connecting, via a select device stacked on top of the plurality of unit cells, the current in the first local digit line to a global digit line; and
determining, via an analog to digit convert connected to the global digit line, the sum from measuring the current as a multiple of a predetermined amount of current.

18. The method of claim 17, wherein the memory cell is programmed to allow a first amount of current to pass through the respective unit cell when a voltage applied on a wordline connected to a gate of the transistor has a level representative of a bit value of one; and the first amount is substantially equal to the predetermined amount multiplied by a weight value stored in the memory cell.

19. The method of claim 18, wherein the weight value is a multi-bit value.

20. The method of claim 18, wherein the plurality of unit cells has a plurality of groups of unit cells; transistors in each respective group among the plurality groups are configured to be applied a same voltage representative of a same bit of data in the input data; memory cells in the respective group are combined to store a multi-bit value; and each memory cell in the respective group is programmed to store a one-bit value.
